(19) United States
(12) Patent Application Publication
(10) Pub. No.: US 2006/0187986 A1
(43) Pub. Date: Aug. 24, 2006

(54) OPTICAL COMMUNICATION MODULE AND MULTI-MODE DISTRIBUTED FEEDBACK LASER DIODE

(76) Inventors: Ming-Yung Jow, Hsinchu City (TW); Zuon-Min Chuang, Taoyuan County (TW); Rung-Ting Lee, Nantou County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/908,984

(22) Filed: Jun. 3, 2005

(30) Foreign Application Priority Data
Feb. 24, 2005 (TW) 94105561

(51) Int. Cl. H01S 5/20; H01S 3/08

(52) U.S. Cl. 372/45.01; 372/98; 372/99; 372/101

(57) ABSTRACT

An optical communication module being adapted to transmit a first optical signal to an optical transmitting device and receive a second optical signal is provided. The optical communication module includes a multi-mode distributed feedback laser diode (MM-DFB LD) and a receiver. The first optical signal is emitted by the MM-DFB LD and propagated by the optical transmitting device. The receiver is disposed at the propagating path of the second optical signal to receive the second optical signal propagated by the optical transmitting device. Moreover, another optical communication module having a lens with asymmetric numerical aperture (NA) is provided. Furthermore, an LD package includes a MM-DFB LD device with KL value ranged from 1.0 and 5.0 is further provided.

### CROSS-REFERENCE TO RELATED APPLICATION

This application claims the priority benefit of Taiwan application serial no. 94105561, filed on Feb. 24, 2005. All disclosure of the Taiwan application is incorporated herein by reference.

### BACKGROUND OF THE INVENTION

1. Field of Invention

The present invention relates to an optical communication module, more particularly to an optical communication module having a Multimode Distributed Feedback Laser Diode (MM-DFB LD) without using an optical isolator therein.

2. Description of Related Art

Nowadays, in accordance with the rapid development of the internet and various sorts of multimedia applications therein, the demand for more applicable bandwidth is increasing. The fiber optical communication techniques, which are previously more often applied in the field of long distance communication, are now likely to be used in short distance communication. In another hand, the field of fiber optical communication is closing to users to satisfy their requirements. The developing and manufacturing of optical communication modules play a key role in the field of optical communication. Conventional optical communication modules utilize laser diodes, such as Fabry-Perot laser diodes or distributed feedback laser diodes, as their light sources.

Generally, conventional Fabry-Perot laser diodes are more often used in short-distance and low-speed optical communication modules known as Fiber To The Curb (FTTC). Such modules are most likely applied in the bandwidth about 1310 nm, due to their dispersion characteristic. In comparing the Fabry-Perot laser diode, DFB LDs have the advantage of being less limited by the dispersion, therefore optical communication modules having distributed feedback diodes are mainly used in the long-distance (>10 km) high-speed optical communication. Remarkably, conventional DFB LDs are single mode distributed feedback laser diodes (SM-DFB LD). Such a conventional optical communication module is illustrated as follows.

FIG. 1 schematically depicts a conventional optical communication module. A GE-PON ONU 1000 Based-PX20 is the example for descriptions. An optical communication module 100 includes a SM-DFB LD 110, a PIN-TIA receiver 120, a reflector 130, an optical isolator 140, and a housing 150. The SM-DFB LD 110 is implemented in the housing 150, for emitting optical signals to an optical fiber 160, transmitting the optical signals thereby to the internet. The PIN-TIA receiver 120 and the reflector 130 are implemented in the housing 150. When the optical signals transmit from the optical fiber 160 to the optical communication module 100, the optical signals transmitted in the optical fiber are reflected to the PIN-TIA receiver 120 by the reflector 130.

Remarkably, since the SM-DFB LDs are relatively sensitive to lights and the reflection of unexpected lights (such as reflection from other optical nods) back from the optical fiber 160 occurs substantially often, an optical isolator is often employed between the SM-DFB LD 110 and the optical fiber 160 to prevent or reduce the interference caused by the reflected lights to the SM-DFB LD 110.

FIG. 2 is a cross-sectional view of a conventional SM-DFB LD. Referring to FIGS. 1 and 2, SM-DFB LD 110 includes a SM-DFB LD device 112. It can be clearly seen from FIG. 2, the SM-DFB LD device 112 usually uses a technology of quarter wavelength shifted grating to improve the yield rate of the single mode, and the anti reflection (AR) layer 114 are formed on both sides of the laser diode. For this type of SM-DFB LD device 112, the design of an grating layer 116 is adjusted to reduce the KL value, wherein K is the coupling coefficient, and L is the cavity length, so as to sustain a certain level for the laser outputting efficiency. Then, since the KL value is relatively lower, the SM-DFB LD device 112 is relatively sensitive to reflected lights. It should be noted that the cost of the SM DFB LD will be seriously affected by the yield of the side mode suppression ratio (SMSR).

In view of the above, due to the expansive costs of the SM-DFB LDs 110 and the optical isolators 140, the cost of manufacturing the optical communication modules 100 is hard to be further reduced.

### SUMMARY OF THE INVENTION

An objective of the present invention is to provide an optical communication module having a Multimode Distributed Feedback Laser Diode (MM-DFB LD) and needing no an optical isolator therein.

Another objective of the present invention is to provide an optical communication module having a distributed feedback laser diode and a lens with asymmetric numerical aperture (NA).

A further objective of the present invention is to provide a MM-DFB LD, which is insensitive to reflected lights or noise of lights.

An optical communication module for transmitting a first optical signal to an optical transmitting device and receiving a second optical signal therefrom is provided in the present invention. The optical communication module includes a MM-DFB LD and a receiver, wherein the MM-DFB LD is suitable for emitting a first optical signal to an optical transmitting device and transmitting the optical signal thereby. The receiver is implemented on the path of the second optical signal to receive the second signal transmitted by the optical transmitting device.

In an embodiment of the invention, the foregoing optical communication module further includes a lens, implemented between the MM-DFB LD and the optical transmitting device. In a preferred embodiment, the lens is integrated in the MM-DFB LD. In addition, one side of the lens adjacent to the MM-DFB LD has a first numerical aperture, and the side of the lens adjacent to the optical transmitting device has a second numerical aperture.

In an embodiment of the invention, the optical communication module can further include a reflector, which is implemented between the optical transmitting device and the receiver, as well as on the transmitting path of the second optical signal.

In an embodiment of the invention, the optical communication module can further include a housing, wherein the MM-DFB LD and the receiver are implemented within the housing.

In an embodiment, the MM-DFB LD includes a supporter, a MM-DFB LD device and a cover. The MM-DFB LD device is implemented on and electrically connected to the supporter. The cover covers the MM-DFB LD device and at least a portion of the supporter. The MM-DFB LD comprises a substrate, a buffer layer, a first cladding layer, an active layer, a second cladding layer, a contacting layer and a grating layer, wherein the buffer layer is implemented on the substrate, the first cladding layer is implemented on the buffer layer, the active layer is implemented on the first cladding layer, the second cladding layer is implemented on the active layer, the contacting layer is implemented on the second cladding layer, and the grating layer is embedded between the first and the second cladding layers.

In an embodiment of the invention, the KL value of the foregoing MM-DFB LD device is, for example, between 1.0 and 5.0.

In an embodiment of the invention, the optical communication module device can further comprise an anti-reflection (AR) layer and a high reflection (HR) layer, the AR layer being implemented to the outputting surface, the HR layer being implemented to the opposite side of the AR coating.

In an embodiment of the invention, the receiver is, for example, a PIN-TIA receiver.

The present invention further provides an optical communication module, suitable for transmitting a first optical signal to an optical transmitting device and receiving a second optical signal from the optical transmitting device. The optical communication module comprises a DFB LD, a receiver, a lens. The DFB LD is adapted to emit a first optical signal to the optical transmitting device, and the optical transmitting device transmits the optical signal thereby. The DFB LD is, for example, a MM-DFB LD or a SM-DFB LD. The receiver is implemented on the transmitting path of the second optical signal to receive the second optical signal transmitted by the optical transmitting device. In addition, the lens is implemented between the DFB LD and the optical transmitting device. The lens has a first numerical aperture at the side towards the MM-DFB LD and a second numerical aperture at the side towards the optical transmitting device. The first numerical aperture is larger than the second.

According to an embodiment of the present invention, the lens can be integrated to the optical communication module.

In an embodiment of the present invention, the optical communication module can further comprise a reflector, which is implemented between the optical transmitting device and the receiver, as well as on the transmitting path of the second optical signal.

In an embodiment of the present invention, the optical communication module can further comprise a housing, wherein the DFB LD and the receiver are implemented in side the housing.

In an embodiment of the present invention, the DFB LD comprises a supporter, a DFB LD device and a cover. The DFB LD device is implemented on and electrically connected to the supporter. The cover covers the DFB LD and at least a part of the supporter.

In an embodiment of the present invention, the KL value of the present invented DFB LD device is between 1.0 and 5.0.

In an embodiment of the present invention, the DFB LD can further comprise an AR layer and a HR layer, the AR layer being implemented at the outputting surface, the HR layer being implemented at the opposite side of the AR layer.

In an embodiment of the present invention, the receiver of the preferred embodiment of the present invention herein is a PIN-TIA receiver.

The present invention further provides a MM-DFB LD, including a supporter, a MM-DFB LD device and a cover. The MM-DFB LD device is implemented on and electrically connected to the supporter. The MM-DFB LD device has an optical outputting surface. The KL value of the MM-DFB LD device is between 1.0 and 5.0. The cover covers the MM-DFB LD device and at least a part of the supporter.

In an embodiment of the present invention, the MM-DFB LD device comprises a substrate, a buffer layer, a first cladding layer, an active layer, a second cladding layer, a contacting layer and a grating layer. Wherein, the buffer layer is implemented on the substrate, the first cladding layer is implemented on the buffer layer, the active layer is implemented on the first cladding layer, the second cladding layer is implemented on the active layer, the contacting layer is implemented on the second cladding layer, and the grating layer is embedded between the first and the second cladding layers.

In an embodiment of the present invention, the optical communication module device can further include an AR layer and a HR layer, the AR layer being implemented to the outputting surface, the HR layer being implemented to the opposite side of the AR layer.

In the present invention, an optical isolator is not necessarily needed in the present invention, because either a DFB LD having relatively low sensitivity to reflected light or a lens asymmetric numerical aperture is adopted in the present invention. Therefore the production cost can be cut down accordingly.

Other objects and advantages of the present invention will become apparent from the following descriptions.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of a conventional optical communication module.

FIG. 2 is a cross-sectional view of a conventional quarter wavelength shifted SM-DFB LD.

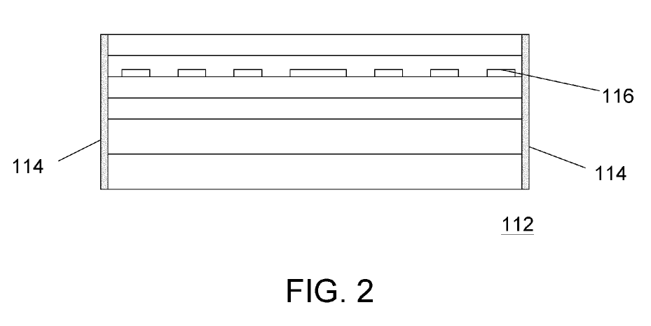

FIG. 3 is a schematic diagram of an optical communication module according to an embodiment of the present invention.

FIG. 4 is a spectrum diagram of a MM-DFB LD.

FIG. 5 is a cross-sectional view of a MM-DFB LD device according to an embodiment of the present invention.

FIG. 6 is a cross-sectional view of a MM-DFB LD TO Can according to an embodiment of the present invention.

FIG. 7A is a diagram of the relationship between the wavelength and the temperature of the MM-DFB LD.

FIG. 7B is a diagram of the relationship between the spectrum width and the temperature of the MM-DFB LD.

### DESCRIPTION OF THE PREFERRED EMBODIMENTS

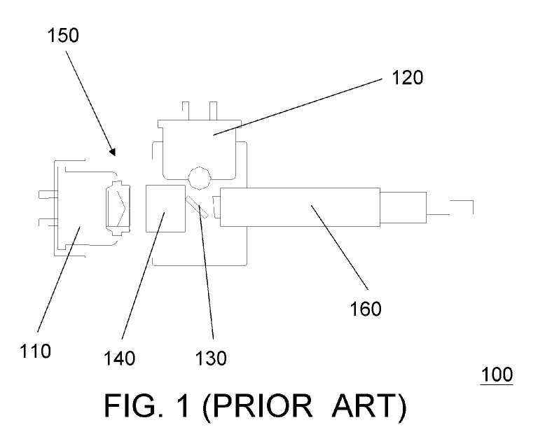

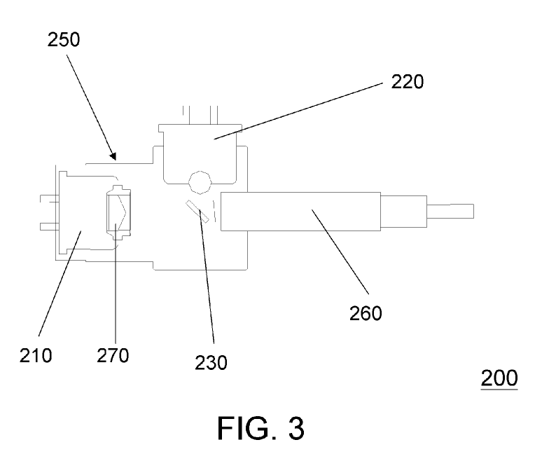

FIGS. 3 is a schematic diagram of an optical communication module according to an embodiment of the present invention. The optical communication module 200 of the present invention is adapted to transmit a first optical signal to an optical transmitting device 260, and receive a second optical signal from the optical transmitting device 260. In FIG. 3, the optical communication module 200 comprises a MM-DFB LD 210 and a receiver 220, wherein the MM-DFB LD is adapted to emit a first optical signal to an optical transmitting device 260, and transmit the first optical signal thereby to the internet. The receiver 220 is implemented on the transmitting path of the second optical signal to receive the second optical signal transmitted from the optical transmitting device 260. In this preferred embodiment, the optical transmitting device 260 is, for example, one selected from the group consisting of optical fiber, optical waveguide and any other equivalent transmitting devices. Remarkably, in comparing with the conventional SM-DFB LD 110 (see FIG. 1), the preferred embodiment adopts a MM-DFB LD 210 as a light source, which is insensitive to reflected lights, therefore the optical communication module 200 does not necessarily need an optical isolator therein, and then the production cost can be cut down accordingly.

In an embodiment of the present invention, the optical communication module 200 can further comprise a reflector 230. The reflector 230 is implemented between the optical communication device 260 and the receiver 220, as well as on the transmitting path of the second optical signal. The purpose of implementing the reflector 230 therein is to reflect the second optical signal to the receiver 220 with a specific angle. However, in the present invention, the reflector 230 is not absolutely needed for the optical communication module. It should be noted that specific embodiments of, and examples for, the invention are described herein for illustrative purposes, various equivalent modifications are possible within the scope of the invention, as those skilled in the relevant art will recognize that the reflector 230 is omissible by adjusting the positions of the MM-DFB LD 210 and the receiver 230.

Referring to FIG. 3, the optical communication module 200 of the embodiment can further include a housing 250 to adapt the MM-DFB LD 210, the receiver 220 and the reflector 230 therein. Those skilled in the relevant art will recognize that the present invented MM-DFB LD 210 and receiver 220 can also be integrated inside any other optical products but not to this specific housing 250.

Still in FIG. 3, the optical communication module 200 of the embodiment can further include a lens 270, wherein the lens 270 is implemented between the MM-DFB LD 210 and the optical transmitting device 260. It is preferred to integrate the lens 270 onto the MM-DFB LD 210 (shown as FIG. 3).

Remarkably, the lens 270 can be either a lens with a single numerical aperture or a lens with an asymmetric numerical aperture. The lens with an asymmetric numerical aperture is taken as the example. The lens 270 has a first numerical aperture at the side towards the MM-DFB LD 210 and a second numerical aperture at the side towards the optical transmitting device 260, the first numerical aperture is larger than the second numerical aperture. Such a design allows the MM-DFB LD 200 to be less interfered by the reflected lights. It is also to be noted that the shape, the quantity and the position of the lens 270 may vary according to the practical requirements.

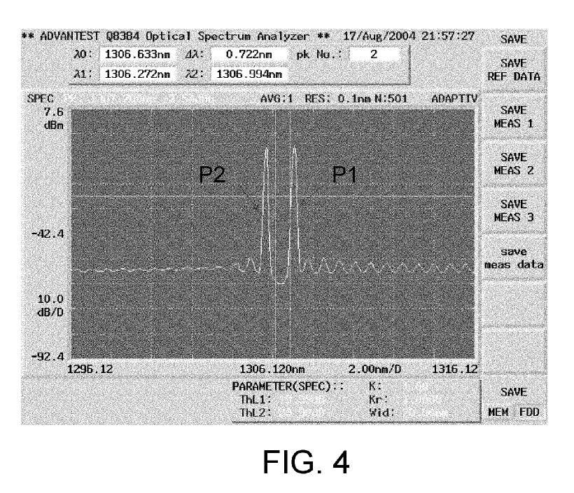

FIG. 4 is a spectrum diagram of a MM-DFB LD. Referring to FIG. 4, the spectrum of the MM-DFB LD in the embodiment has two peaks P1 and P2 (P1≦P2) near the position of 1310 nm with SMSR=|[−10*log (P1/P2)]|, wherein it satisfies the condition of SMSR=|[−10*log (P1/P2)]|<30 dB. Accordingly, it is defined as MM-DFB LD by the present invention when the spectrum of the MM-DFB LD satisfies the condition of SMSR=|[−10*log (P1/P2)]|<30 dB. Whereas, the present invention defines a DFB LD as a SM-DFB LD when the spectrum of the DFB LD satisfies the condition of SMSR=|[−10*log (P1/P2)]|>30 dB.

According to FIG. 4, the peaks P1 and P2 are only for example to illustrate the present invention, while the quantity of the peaks and the condition of P1<P2 should not be construed as a limitation thereof. In another words, when a spectrum of a DFB LD has two or more than two peaks P1, P2, . . . Pn, and the peaks satisfy the condition of SMSR=|[−10*log (Px/Py)]|<30 dB, wherein 1<x<n, 1<y<n, and x≠y, then the DFB LD can be called a MM-DFB LD.

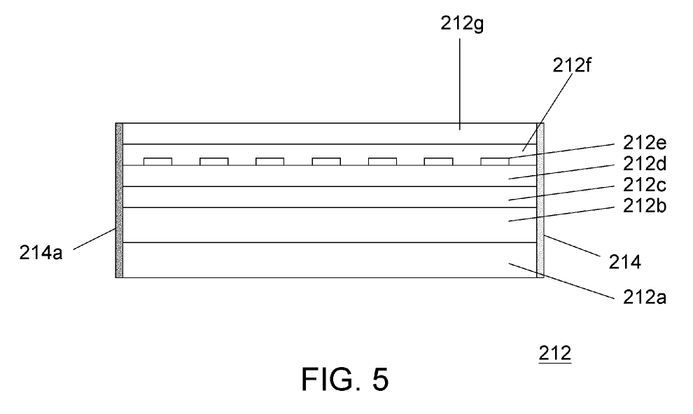

FIG. 5 is a cross-sectional diagram of a MM-DFB LD device according to the present invention. Referring to FIG. 5, the preferred embodiment of the present invented MM-DFB LD device 212 includes, for example, a substrate 212a, a buffer layer 212b, a first cladding layer 212c, an active layer 212d, a grating layer 212e, a second cladding layer 212f and a contacting layer 212g, wherein the buffer layer 212b is implemented on the substrate 212a, the first cladding layer 212c is implemented on the buffer layer 212b, the active layer 212d is implemented on the first cover layer 212c, the second cladding layer 212f is implemented on the active layer 212d, the contacting layer 212g is implemented on the second cladding layer 212f, and the grating layer 212d is embedded between the first and the second cladding layers 212c and 212f. It is to be noted that the KL value of the MM-DFB LD device 212 in the embodiment is between 1.0 and 5.0.

Referring to FIG. 5, the MM-DFB LD device 212 of the preferred embodiment can further include an AR layer 214 and a HR layer 214a. The AR layer 214 is disposed on the outputting surface, and the HR layer 214a is disposed at the opposite side of the AR layer 214. Because it employs a design of an AR layer 214 and a HR layer 214a in the embodiment, and it has a KL value ranged from 1.0 to 5.0, the MM-DFB LD chip 212 of the present invention is insensitive to the reflected lights, and therefore an optical isolator is not necessary in the present invention.

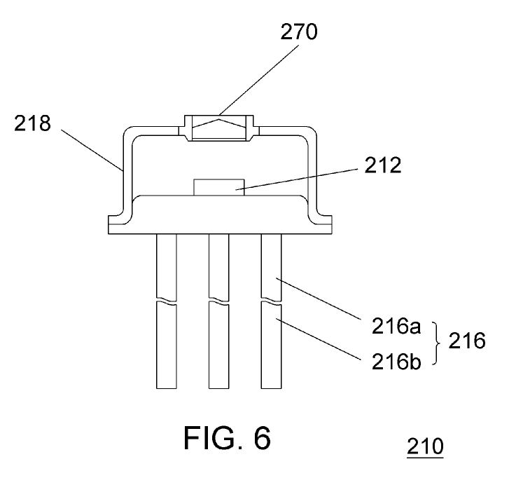

FIG. 6 is a cross-sectional diagram of a MM-DFB LD TO Can according to the present invention, wherein TO Can is a known as a packaging technology. Referring to FIG. 6, the MM-DFB LD 210 of the embodiment includes a supporter 216, the MM-DFB LD device 212 and a cover 218. The MM-DFB LD device 212 is implemented on and electrically connected to the supporter 216. The cover 218 covers the MM-DFB LD device 212 and at least a part of the supporter 216. The supporter 216 includes two parts of circuit board 216a and connection pin 216b, wherein the circuit board 216a is used to support the MM-DFB LD device 212 and/or other devices (such as detector) thereon, and the connection pin 216b is electrically connected with the MM-DFB LD device 212 and/or other devices through the circuit board 216a.

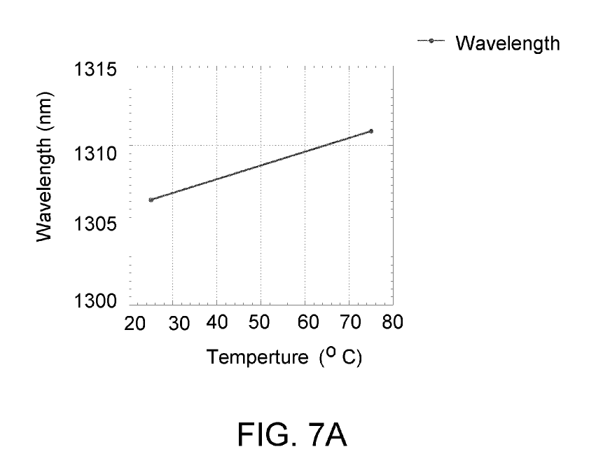

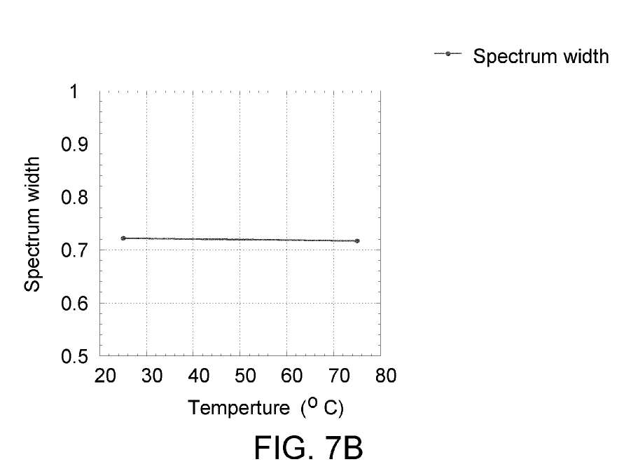

FIG. 7A is a diagram of the relation between the wavelength and the temperature of the MM-DFB LD, while FIG. 7B is a diagram of the relation between the spectrum width and the temperature of the MM-DFB LD. Referring to FIGS. 7A and 7B, when the MM-DFB LD is operated under the temperature ranged from 25 to 75 Celsius degrees, the wavelength of the lights emitted from the MM-DFB LD is ranged from 1306 nm to 1311 nm, and the spectrum width is about 0.72 nm. The relation between the ranges of the wavelength and the spectrum width can satisfy the standard of IEEE 802.3ah standard. It should be noted that the IEEE 802.3ah standard is specifically taken herein for illustrative purposes. The scope of the present invention should not be limited by above quotation, as those skilled in the relevant art will recognize that the present invention is also adapted to other optical communication standard such as ITU-T G.957 etc.

TABLE 1

| | RMS Frequency Bandwidth |
|---|---|
| Central Wavelength | (1000BASE-PX20-U Standard) |
| Unit(nm) | Unit(nm) |
| 1260 | 0.72 |
| 1270 | 0.86 |
| 1280 | 1.07 |
| 1290 | 1.40 |
| 1300 | 2.00 |
| 1304 | 2.42 |
| 1305 | 2.55 |
| 1308 | 3.00 |
| 1317 | 3.00 |
| 1320 | 2.53 |
| 1321 | 2.41 |
| 1330 | 1.71 |
| 1340 | 1.29 |
| 1350 | 1.05 |
| 1360 | 0.88 |

It should be noted that deriving from the above disclosure to another optical communication module can be obtained. The optical communication module includes a DFB LD, a receiver and a lens, of which components the structure and the relation among the components have been previously described above and are not repeated. Specifically, in the invention, a MM-DFB LD or a SM-DFB LD can be implemented with a lens having an asymmetric numerical aperture. The interference of the reflected lights can therefore be reduced by employing such implementation in the optical communication module.

In view of the above, because the present invention employs an above described MM-DFB LD having an AR layer implemented to one side and a HR layer to the other side, the optical output efficiency is therefore higher and thus the MM-DFB LD is able to adopt a grating having a larger KL value to reduce the sensitivity to the back reflection of the optical communication module. At the mean time, since a MM-DFB LD has a better output efficiency, an optical communication module having a MM-DFB LD can further reduce the interference of the reflected lights by reducing optical coupling efficiency. According to a combination of the above specific designs, the expensive optical isolator can be removed from the optical communication module.

Further, since the MM-DFB LD in the invention includes a grating having a larger KL value, the resistance to back reflection is better, and the requirement of SMSR specification for the MM-DFB LD is relatively loose. And therefore, the fabrication yield can be improved, and the fabrication cost is reduced.

In view of the above, the present invention has at least the advantages as follows.

1. The optical transmitting module of the invention is designed without using the optical isolator, and the production cost can be reduced accordingly.

2. The optical communication module of the invention can effectively prevent the DFB LD from being interfered by the reflected lights by employing a lens having an asymmetric numerical aperture.

3. The MM-DFB LD of the invention in accordance with design uses an AR layer and a HR layer thereof, by which the laser outputting efficiency can be therefore increased.

Other modifications and adaptations of the above-described preferred embodiment of the present invention may be made to meet particular requirements. This disclosure is intended to exemplify the invention without limiting its scope. All modifications that incorporate the invention disclosed in the preferred embodiment are to be construed as coming within the scope of the appended claims or the range of equivalents to which the claims are entitled.

What is claimed is:

1. An optical communication module, suitable for use in transmitting a first optical signal to an optical transmitting device, and receiving a second optical signal from the optical transmitting device, comprising:
a multi-mode distributed feedback laser diode (MM-DFB LD), being adapted to emit the first optical signal to the optical transmitting device and transmitting the optical signal through the optical transmitting device; and
a receiver, implemented on a path of the second optical signal to receive the second signal transmitted by the optical transmitting device.

2. The optical communication module according to claim 1, further comprising a lens being implemented between the MM-DFB LD and the optical transmitting device.

3. The optical communication module according to claim 2, wherein the lens is integrated to said MM-DFB LD.

4. The optical communication module according to claim 2, wherein the lens has a first numerical aperture at a first side towards the MM-DFB LD and a second numerical aperture at a second side towards the optical transmitting device, the first numerical aperture being larger than the second numerical aperture.

5. The optical communication module according to claim 1, further comprising a reflector, implemented between the optical transmitting device and the receiver, as well as on a transmitting path of the second optical signal.

6. The optical communication module according to claim 1, further comprising a housing, wherein the MM-DFB LD and the receiver are implemented inside the housing.

7. The optical communication module according to claim 1, wherein the MM-DFB LD comprises:
a supporter;
a MM-DFB LD device being implemented on and electrically connected to the supporter and having an optical outputting surface; and
a cover, covering over the MM-DFB LD and at least a portion of the supporter.

8. The optical communication module according to claim 7, wherein the MM-DFB LD device comprises:
a substrate;
a buffer layer, implemented on the substrate;
a first cladding layer, implemented on the buffer layer;
an active layer, implemented on the first cladding layer;
a second cladding layer, implemented on the active layer;
a contacting layer, implemented on the second cladding layer; and
a grating layer, embedded between the first and the second cladding layers.

9. The optical communication module according to claim 7, wherein the MM-DFB LD device has a KL value ranged from 1.0 to 5.0.

10. The optical communication module according to claim 7, wherein the MM-DFB LD device further comprises:
an anti-reflection (AR) layer, implemented to the outputting surface; and
a high-reflection (HR) layer, implemented to a side opposite to the AR layer.

11. The optical communication module according to claim 1, wherein the receiver is a PIN-TIA receiver.

12. An optical communication module, being adapted to transmit a first optical signal to an optical transmitting device, and receive a second optical signal from the optical transmitting device, the optical communication module comprising:
a distributed feedback laser diode (DFB LD), being adapted to emit a first optical signal to an optical transmitting device and transmitting the optical signal thereby;
a receiver, being implemented on the path of the second optical signal to receive the second signal transmitted by the optical transmitting device; and
a lens, being implemented between the DFB LD and the optical transmitting device, wherein the lens has a first numerical aperture at a first side towards the DFB LD and a second numerical aperture at a second side towards the optical transmitting device, the first numerical aperture being larger than the second numerical aperture.

13. The optical communication module according to claim 12, wherein the DFB LD is either a multi-mode DFB LD or a single-mode DFB LD.

14. The optical communication module according to claim 12, wherein the lens is integrated to the DFB LD.

15. The optical communication module according to claim 12, further comprising a reflector, which is implemented between the optical transmitting device and the receiver, as well as on a transmitting path of the second optical signal.

16. The optical communication module according to claim 12, further comprising a housing, wherein the DFB LD and the receiver are implemented inside the housing.

17. The optical communication module according to claim 12, wherein the DFB LD comprises:
a supporter;
a DFB LD device being implemented on and electrically connected to the supporter and having an optical outputting surface; and
a cover, covering the DFB LD and at least a part of the supporter.

18. The optical communication module according to claim 17, wherein the DFB LD device has a KL value ranged from 1.0 to 5.0.

19. The optical communication module according to claim 17, wherein the DFB LD device further comprises:
an anti-reflection (AR) layer, implemented at the outputting surface; and
a high-reflection (HR) layer, implemented at a side opposite to the AR layer.

20. The optical communication module according to claim 1 7, wherein the receiver includes a PIN-TIA receiver.

21. A multi-mode distributed feedback laser diode (MM-DFB LD), comprising:
a supporter;
a MM-DFB LD device, which has a KL value ranged from 1.0 to 5.0, and is implemented on and electrically connected to the supporter, and has an optical outputting surface; and
a cover, covering over the MM-DFB LD and at least a portion of the supporter.

22. The MM-DFB LD according to claim 21, wherein the MM-DFB LD device comprises:
a substrate;
a buffer layer, implemented on the substrate;
a first cladding layer, implemented on the buffer layer;
an active layer, implemented on the first cladding layer;
a second cladding layer, implemented on the active layer;
a contacting layer, implemented on the second cladding layer; and
a grating layer, embedded between the first and the second cladding layers.

23. The MM-DFB LD according to claim 21, wherein the MM-DFB LD device further comprises:
an anti-reflection (AR) layer, implemented at the outputting surface; and
a high-reflection (HR) layer, implemented on a side opposite to the AR layer.
